(19) United States
(12) Patent Application Publication
(10) Pub. No.: US 2026/0226607 A1
(43) Pub. Date: Aug. 6, 2026

(54) IN-LINE WEB MATERIAL PROCESSING MACHINE AND METHOD FOR PRODUCING A COATED MATERIAL

(71) Applicant: Stora Enso OYJ, Helsinki (FI)

(72) Inventors: Tommi Nordström, Turku (FI); Kaj Backfolk, Lappeenranta (FI); Kalle Ekman, Stockholm (SE)

(73) Assignee: Stora Enso OYJ, Helsinki (FI)

(21) Appl. No.: 19/154,914

(22) PCT Filed: Feb. 8, 2024
(86) PCT No.: PCT/IB2024/051168

§ 371 Date: Aug. 8, 2025

(30) Foreign Application Priority Data
Feb. 9, 2023 (SE) 2330071-8

(51) Int. Cl. C23C 14/56; C23C 14/24

(52) U.S. Cl. CPC C23C 14/562; C23C 14/24

(57) ABSTRACT

An in-line web material processing machine (1) for producing a coated material is disclosed. The processing machine comprises a process vacuum chamber (31) housing an unwinder reel holder for holding a first supply roll (51) of web material (2) to be processed and a vacuum coating unit (52) for deposing a coating on the web material. A loading vacuum chamber (32) housing a second supply roll of web material to be processed is provided, with an inlet closure (321) arranged between the process vacuum chamber (31) and the loading vacuum chamber (32). The inlet closure (321) is arranged to be moved between a closed state, in which the vacuum chambers are separated from each other, and an open state, in which access is provided between the vacuum chambers. An automatic reel change system (4) is operable to move the second supply roll of web material from the loading vacuum chamber (32) to the process vacuum chamber (31) under vacuum when the inlet closure (321) is in the open state and to change a supply roll (51) on the unwinder reel holder from the first supply roll to the second supply roll under vacuum.

### TECHNICAL FIELD OF THE INVENTION

The present invention relates to an in-line web material processing machine for producing a coated material, and in particular coated paperboard, as well as to a method for vacuum coating of a web material.

### BACKGROUND OF THE INVENTION

Coated web materials, such as coated paperboard, are used for example as packaging materials. The coating may e.g. serve as a barrier against moisture, water, oxygen, and the like. Such coated web materials are e.g. used as packaging materials for food, pharmaceuticals, electronic devices, and other types of products containing liquid or gas, or being sensitive to moisture, water, oxygen or the like. Such a coating is often used in combination with other layers, such as one or more polymer layers.

The barrier coating layer may e.g. be provided by vacuum coating, such as metallization, in a vacuum coating unit. It is per se known to form such vacuum coatings onto a web material in an in-line process, such as a roll-to-roll process. Such vacuum coating processes are e.g. disclosed in WO 2022/090337 and US 2020/0165721. In these known systems, a vacuum chamber is provided in which a supply roll of web material is arranged, as well as a vacuum coating unit and a rewinding roll.

However, known vacuum coating processes are not well suited for applying coatings on thicker web materials, such as paperboard. Thicker web materials often contain more moisture, which makes evacuation of the vacuum chamber to obtain an adequate low pressure tedious. An option would be to use more efficient vacuum pumps, but this would lead to increased costs and may still not address problems such as low run time. Further, supply rolls of thicker web materials generally contain much lower lengths of web material than supply rolls of thinner web materials, which means that the supply roll need to be replaced much more frequently. Overall, this makes coating of thicker web materials in this way tedious, cumbersome and expensive.

The solution to this problem has been to provide the barrier coating layer on a thin film or web material, such as paper or polymer film, and to laminate this onto the thicker web material. Hereby, the thicker web material need not be provided in vacuum, since the lamination can take place at atmospheric pressure. However, this solution requires separate production lines for producing the coated thin web material and to laminate it to the thicker web material, making also this process tedious, cumbersome and expensive.

There is therefore still a need for a more cost-efficient and speedy method and apparatus for providing a coating on a web material, such as a barrier coating on paperboard, and in particular for relatively thick paperboard.

### SUMMARY OF THE INVENTION

It is therefore an object of the present invention to at least partly alleviating the above-discussed problems of the prior art and to address this need.

This object is obtained with an in-line web material processing machine and a method for vacuum coating of a web material as defined in the appended claims.

According to a first aspect of the invention, there is provided an in-line web material processing machine for producing a coated material comprising:
a process vacuum chamber housing an unwinder reel holder for holding a first supply roll of web material to be processed and a vacuum coating unit for deposing a coating on the web material;
a loading vacuum chamber housing a second supply roll of web material to be processed;
an inlet closure arranged between said process vacuum chamber and said loading vacuum chamber, the inlet closure being arranged to be moved between a closed state, in which the processing vacuum chamber and the loading vacuum chamber are separated from each other, to an open state, in which access is provided between the processing vacuum chamber and the loading vacuum chamber; and
an automatic reel change system operable to move said second supply roll of web material from said loading vacuum chamber into said process vacuum chamber under vacuum when said inlet closure is in the open state and to change a supply roll on said unwinder reel holder from said first supply roll to said second supply roll under vacuum.

The in-line web processing machine may comprise a single vacuum coating unit, but may alternatively comprise more than one vacuum coating units, such as two or three vacuum coating units. In case two or more vacuum coating units are provided, these may be arranged in one and the same process vacuum chamber, or, alternatively, be arranged in two or more separate process vacuum chambers.

The loading vacuum chamber may be arranged as an extension in the general direction of the processing line for the web material. The inlet closure would in such a situation also be directed, and preferably aligned with, the general direction of the processing line. In this case, the system may be referred to as a back-loaded system. However, alternatively, the loading vacuum chamber may be arranged laterally from the general direction of the processing line for the web material. The inlet closure would in such a situation also be directed laterally in relation to the general direction of the processing line. In this case, the system may be referred to as a side-loaded system.

The in-line web material processing machine provides a coating on a web material, such as paperboard, in a single, in-line process. The process may be performed with an endless web.

Preferably, the machine operates in a roll-to-roll process, in which the web material to be processed is provided on a supply roll and the processed, coated web material is wound on rewind roll. However, the processed, coated web material may also, alternatively, be cut into sheets, in a roll-to-sheet process, or be taken care of in other ways. The processed, coated web material may also, additionally, or alternatively, continue into further in-line processes, such as in-line lamination, extrusion coating, and/or printing.

Due to the provision of the loading vacuum chamber, the entire operation becomes faster, simpler and more cost-efficient.

During production, a load opening of the loading vacuum chamber may be opened and a supply roll may be loaded into the loading vacuum chamber, at atmospheric pressure. At the same time, the process may be running with another supply roll, or several supply rolls, in the processing vacuum chamber at vacuum pressure. The inlet closure, forming a passage between the loading vacuum chamber and the processing vacuum chamber, is at this time closed. When the new supply roll has been loaded into the loading vacuum chamber, the load opening of the loading vacuum chamber may be closed and air and moisture be evacuated by a pump to form a vacuum in the loading vacuum chamber.

Especially for thicker paperboard and the like, containing much moisture, it may take some time to reach an adequate vacuum pressure level, such as 20-30 minutes. Faster evacuation, to reach an adequate vacuum pressure in a shorter time, could be obtained by use of more powerful vacuum pumps, etc. However, since the process in the processing vacuum chamber is running in the meantime, the overall processing time is still reduced, and the entire process made more efficient. In particular, a long evacuation time is of no matter, as long as it is shorter than the time it takes to process a roll of web material in the processing vacuum chamber. Thus, the invention enables the use of less powerful and less costly vacuum systems.

The present invention also provides a more efficient process in terms of runnability and waste control, since shorter runs generally leads to more waste whereas longer runs reduces the amount of waste generated.

More than one loading vacuum chambers may also be used. In this case, a first loading vacuum chamber may be used to evacuate moisture from the supply roll in an initial stage, before entering the second loading vacuum chamber. This may be used to use the processing vacuum chamber more efficiently, in particular for fast coating processes.

Before the web material on the supply roll in the processing vacuum chamber has been unwounded to its end, and when the vacuum pressure in the loading vacuum chamber has reached an acceptable pressure level, the inlet closure between the loading vacuum chamber and the processing vacuum chamber is opened. At this time, the pressure levels of the two chambers are preferably essentially the same. However, a slight difference in pressure may also be acceptable. The pressure within the chambers will be equalized in both chambers once the inlet closure has been opened, thereby forming an open passage between the chambers. The pressure difference is preferably small, or even non-existent. Preferably, the optional pressure difference between the chambers prior to opening is small enough to ensure that an adequate pressure level is maintained in the processing vacuum chamber even after opening of the passage, thereby ensuring that the coating process can continue as before even at this time.

When the inlet closure has been opened, i.e. brought to the open state, the new supply roll may be moved from the loading vacuum chamber to the process vacuum chamber. The old supply roll, already in use in the processing vacuum chamber, could then be exchanged to the new supply roll, coming from the loading vacuum chamber, either when the inlet closure is still opened, or after again having been closed. The switch is performed by the automatic reel change system, as per se known in the art.

The web material from the fresh supply role is preferably spliced to the web material of the old supply role, thereby allowing the process in the processing vacuum chamber to continue without interruption.

After the change of supply rolls, or prior to this change, the inlet closure between the loading vacuum chamber and the processing vacuum chamber is again closed. The coating process in the processing vacuum chamber may then continue, whereas the loading vacuum chamber is reloaded. In this reloading process, the pressure in the loading vacuum chamber is increased to atmospheric pressure, the load opening is opened for introduction of a new supply roll, the load opening is again closed, and the pressure is lowered to a vacuum pressure level.

The process may be repeated for as many times as needed or found suitable for other reasons, such as the need for maintenance, etc.

In this way, two, three or more supply rolls of web material may be processed in a continuous process, without any interruption for reel and roll changes. For example, the process may be repeated to form a continuous process without any interruption for at least 5 supply rolls, and preferably at least 10 supply rolls.

With the present invention, a continuous process, without stop, for web material is enabled, the web being over 10 km long, and preferably over 50 km, and more preferably over 75 km, and most preferably over 100 km.

The vacuum coating unit, also referrable to as vacuum coater, may be of a type as is per se previously known. The vacuum coating unit may e.g. be realized as disclosed in US 2020/0165721 and/or WO 2022/090337, both said documents hereby being incorporated in their entirety by reference.

Preferably, the vacuum coating unit is a vapor deposition unit. The vapor deposition unit may be a physical vapor deposition unit using a coating material in a liquid or solid state or a chemical vapor deposition unit using a chemical vapor. Sometimes such vapor deposition units are called metallizers even if the coating material is not necessarily a metal in the strict sense but could also be a partially oxidized metal, such as AlOₓ or Al₂O₃, or other vapor deposited inorganic materials, such as SiOₓ or SiO₂. Such vapor deposition units are suitable for providing films or layers of coating material in a precise and efficient manner.

The coating provided by the vacuum coating unit can e.g. be a metallization, an organic coating and/or a ceramic coating. Hybrid or mixtures of the above-discussed materials may also be used, such as an Si doped Al layer. The vacuum coating unit may be arranged to deposit a coating on the web material of a vapor deposited inorganic material, such as metal or metal oxide, and preferably aluminum or aluminum oxide.

However, alternatively the vacuum coating unit may be a physical vapor deposition unit, e.g. arranged to provide EB-PVD. The vacuum coating unit may also be arranged to provide the coating by sputtering, such as magnetron sputtering.

In a preferred embodiment, the coating comprises, or is entirely made of, aluminum or aluminum oxide. However, other materials may also be used, such as silicon oxide, carbon, e.g. in the form of Diamond Like Carbon, DLC, and the like.

The coating preferably forms a barrier against liquids, such as water, and/or gases, such as vapor or oxygen. The coating preferably forms a gas impermeable barrier layer.

The coating is preferably relatively thin, such as in the range from 10 nanometers to 500 nanometers. Such thin coatings may not provide barrier against liquid but is mostly used to provide barrier against water vapor, or gases, such as oxygen or CO₂, aroma, and/or radiation, such as light or UV light. Possibly, it could also provide a barrier against greases and oils or aromatics. In order to provide a good barrier, the vacuum coated layers are preferably arranged on relatively smooth and dense surfaces in order to provide a pinhole free surface.

However, thicker coatings may also provide impermeability to liquids etc. Further, as mentioned in the foregoing, additional plastic or polymer layer(s) may be added, preferably on top of the coating, to provide scratch resistance or durability to the vacuum coated layer, but may additionally or alternatively be used to form a liquid barrier and heat sealability.

The vapor coating unit may comprise a chamber in which a wire of coating material, e.g. aluminum, is fed onto individual, resistance-heated inter-metallic evaporators such that the wire becomes molten and evaporates.

The coating preferably has a much lower thickness than the thickness of the web material. The coating may e.g. have a thickness of less than 1% of the thickness of the web material. The coating may e.g. have a thickness in the range of 10-500 nm, and preferably 20-300 nm.

According to an embodiment the vacuum coating unit comprises an area for guiding the web material. This could be for example a processing drum for supporting the web material to be processed. Another possibility could be for example to guide the web in a free span manner without the use of a processing drum. In the free span arrangement the web material to be vacuum coated is held in an unsupported/free span arrangement between supporting rollers with the evaporation source and evaporant material applied via evaporation and condensing the evaporant on the web material in an unsupported and uncooled manner. An advantage with the drum embodiment is e.g. the cooling effect provided by the drum. An advantage of the free span arrangement is e.g. the reduced risk of deformation of the web material and the coating.

The process vacuum chamber may comprise a single vacuum zone, accommodating the vacuum coating unit, the supply roll, and optionally also the rewind roll. However, the process vacuum chamber may alternatively comprise two or more separated vacuum zones, which may have different vacuum pressures, as is per se known in the art. For example, a vacuum zone having lower pressure may be arranged at the vacuum coating unit, where the coating takes place, whereas a slightly higher pressure may be provided to accommodate the supply roll and the optional rewind roll.

For example, the vacuum pressure in the part of the process vacuum chamber where the coating takes place may be a low vacuum pressure of 1×10⁻⁵ bar or less, and preferably 1×10⁻⁶ bar or less, and preferably 1×10⁻⁷ bar or less. Such a low vacuum pressure is beneficial for the coating process since it makes the coating material easier to evaporate and making it possible to evaporate the coating material at a lower temperature. In addition, the low vacuum pressure lowers the risk of the evaporated atoms to be scattered by residual gas molecules, and to possibly react with such residual gas molecules.

Such a low vacuum pressure may be provided in the entire process vacuum chamber. However, alternatively, the low vacuum pressure may be provided only in a high vacuum zone accommodating the vacuum coating unit. One or more additional vacuum zones in the process vacuum chamber may have a slightly higher vacuum pressure, such as 1×10⁻⁵ bar or more, and preferably 1×10⁻⁴ bar or more, such as about 1×10⁻³ bar or more.

The vacuum zones are preferably not provided with totally air tight separation, and a small gap may exist between the zones, e.g. large enough for the web to be coated to moved through. The separation may e.g. be provided in the form of separation walls extending to a position close to a processing drum or the like where coating is applied by the vacuum coating unit. More than two zones, such as three zones, may also be used.

The automatic reel change system may be of any type per se known in the art, and used for example for reel changes in printing presses. Such automatic reel change systems are e.g. known from U.S. Pat. Nos. 3,907,235, 4,111,741, 4,077,580, 4,278,213, 4,233,104, 4,875,633, etc, all of said documents hereby being incorporated in their entirety by reference.

Due to the automatic reel change system, a so-called flying roll change can be performed, to that upon depletion of a roll of material, the coating process need not be stopped. In this process, the old, depleted or almost depleted supply roll is exchanged to a new supply roll. The new web material, of the new supply roll, is preferably spliced or in other ways connected to the old web material, of the old supply roll. Hereby, a continuous, endless web material is formed. The splicing may e.g. be obtained by adhesive tapes, by adhesive, or the like. For this purpose, the new supply roll may be provided with an adhesive tape, gluing spots or the like, on an outer layer, for use in accomplishing a connection with the web material of the roll of material which is running out.

During on-the-fly roll change, the fresh web material is then accelerated to a circumferential speed corresponding to the web speed of the established roll of material. In the course of the actual web change, the start of the web of the fresh roll of material is connected with the web of material on the roll of material which is running out, and the web of material on the roll of material which is running out is cut at substantially the same time. In this way, the start of the web of the fresh web of material is drawn into the coating process by the old web of material and a stoppage of the process is avoided.

The web material to be processed is preferably a fiber-based material, and more preferably a cellulose-based material, and more preferably at least one of a paperboard material, a thick paper and a low density, bulky paper, and most preferably a paperboard material. The machine and method of the present invention is particularly useful for such materials having a relatively great thickness and/or a relatively great grammage.

The web material to be processed preferably has a grammage of at least 150 g/m², and preferably of at least 200 g/m², and more preferably of at least 250 g/m². The grammage is preferably not more than 650 g/m². In an embodiment, the web material to be processed may have a grammage in the range of 200-650 g/m². Grammage may be determined in accordance with the standard ISO 536.

However, the web material may also have a lower grammage, such as 60 g/m² or more, in particular for paper material with very high thickness or high bulk.

The density of the web material to be processed in at least one layer is preferably less than 950 kg/m³, and preferably less than 700 kg/m³, and more preferably less than 600 kg/m³, and most preferably less than 550 kg/m³, as determined in accordance with ISO 534. The material may be a single layer material, having the same, uniform, density in all layers. However, the material may also be a multi-layer material, a multiply. In such embodiments, the density may be different in different layers. The low density as discussed above may in such embodiments be provided in at least one of the layers.

In an embodiment, the web material to be processed has a grammage of 60 g/m² or more and a density of less than 700 kg/m³, and preferably less than 650 kg/m³, and more preferably less than 600 kg/m³, and most preferably less than 550 kg/m³.

The web material to be processed preferably has a thickness of at least 300 microns, and preferably of at least 350 microns, and more preferably of at least 500 microns. The thickness is preferably not more than 1500 microns. In an embodiment the thickness is in the range of 350-1000 microns. The thickness may be determined in accordance with the standard ISO 534.

Materials, and in particular paperboard or thick paper, having such a thickness and/or grammage is generally difficult to handle in an effective way in currently available coating solutions, but can easily be handled by the machine and method of the present invention.

The web material preferably has a relatively smooth surface, at least on the side to be coated. The smoothness may e.g. be expressed in terms of Parker Print Surf (PPS) roughness. The surface roughness in um of the surface may be determined by a Parker Print Surf (PPS) device operated at a clamping pressure of 1.0 MPa, such as devices available from Testing Machines Inc., New York, USA. The web material preferably has a PPS 1.0 Smoothness of less than 3.0 microns. The Parker Print Surf (PPS) roughness may be determined in accordance with the standard ISO 8791-4.

Another characteristic of the web material that may be used is the bulk value. Bulk is used to measure the ratio of paper thickness to its weight in cubic centimeters per gram. Density is the basis weight, grammage, divided by the caliper, i.e. the thickness. Bulk is the inverse of the density, i.e. caliper divided by grammage. Here, the web material preferably has a bulk of more than 1.20, and more preferably more than 1.4. The bulk value may be determined in accordance with the standard ISO 534.

The coated material leaving processing machine according to the invention may be provided with excellent structural and barrier properties and is very useful for packaging goods, e.g. food, liquids and pharmaceuticals. The invention enables facilitated processing, use of less and less costly materials, and/or improved performance. For example, the invention enables use of a reduced amount of plastic coating, reduced need for additional high barrier structures, and/or a performance not easily achievable with single polymer layers.

The in-line web material processing machine may further comprise a rewinder reel holder for holding a rewinding reel for rewinding of the coated material. Hereby, the processed, coated material may be assembled on a second roll. In this case, the process may be a roll-to-roll process. Such a process is generally the most efficient. However, alternatively the coated material may also be cut into sheets, e.g. already in the processing vacuum chamber, or outside this chamber, in a roll-to-sheet process.

In a roll-to-roll process, the rewinding reel holder is preferably arranged in the processing vacuum chamber.

Alternatively, the coated material may be arranged to be moved out from the processing vacuum chamber through an opening enabling vacuum to be maintained in the processing vacuum chamber, to be wounded on a rewinding roll outside the processing vacuum chamber. Such an opening may e.g. be realized by a narrow slit opening, a gap sluice, or the like, as is per se known in the art.

In case rewinding takes place inside the processing vacuum chamber, it may be contemplated to have the rewinding roll to be larger than the supply rolls, thereby allowing the web material of more than one supply roll to be wounded onto a single rewinding roll. Additionally, or alternatively, it is also feasible to temporarily stop the coating process to change the rewinding roll. Hereby, the pressure in the processing vacuum chamber may be allowed to rise to atmospheric pressure, and the processing vacuum chamber may then be opened to extract the full rewind roll and replace it with an empty reel. The processing vacuum chamber may then again be closed and evacuated to an adequate vacuum level, whereby the coating process may continue as before. Even though this would have a negative effect on productivity, it may be balanced against the costs related to other measures. It should in this respect be noted that restoring vacuum in the processing vacuum chamber is much easier than restoring vacuum should a fresh supply roll have been entered, since a fresh supply roll contains a lot of moisture that then needs to be evacuated. Thus, even in temporarily opening the processing vacuum chamber at the outlet end, and allowing the pressure to return to atmospheric pressure, the vacuum can quite easily be restored in a relatively short time, and without much cost and time waste.

However, in a preferred embodiment, a change of rewind rolls is also performed while still maintaining vacuum in the processing vacuum chamber during the process. Such an exchange of rolls may preferably be performed in a manner similar to the above-discussed exchange of supply rolls.

In such an embodiment, the in-line web material processing machine may further comprise:
an output vacuum chamber;
an outlet closure arranged between said process vacuum chamber and said output vacuum chamber, the outlet closure being arranged to be moved between a closed state, in which the processing vacuum chamber and the output vacuum chamber are separated from each other, to an open state, in which access is provided between the processing vacuum chamber and the output vacuum chamber; and
a second automatic reel change system operable to change a rewinding roll on said rewinder reel holder from a first rewinder roll to a second rewinder roll under vacuum when said outlet closure is in the open state.

Hereby, the coating process may continue uninterrupted, even during an exchange of the rewinding rolls. Before the coated web material on the rewind roll in the processing vacuum chamber has been re-wounded to its full capacity, it is assured that the vacuum pressure in the output vacuum chamber has reached an acceptable pressure level. The outlet closure between the output vacuum chamber and the processing vacuum chamber is opened. At this time, the pressure levels of the two chambers are preferably essentially the same. However, a slight difference in pressure may also be acceptable. The pressure within the chambers will be equalized in both chambers once the outlet closure has been opened, thereby forming an open passage between the chambers. The pressure difference is preferably small, or even non-existent. Preferably, the optional pressure difference between the chambers prior to opening is small enough to ensure that an adequate pressure level is maintained in the processing vacuum chamber even after opening of the passage, thereby ensuring that the coating process can continue as before even at this time.

When the outlet closure has been opened, i.e. brought to the open state, the full rewind roll, already in use in the processing vacuum chamber, could be exchanged to the new rewind roll, coming from the output vacuum chamber. The switch is performed by the second automatic reel change system, as per se known in the art.

The coated web material is then preferably cut and the end attached to the fresh roll, thereby allowing the process in the processing vacuum chamber to continue without interruption.

After the change of rewind rolls, the outlet closure between the output vacuum chamber and the processing vacuum chamber is again closed. The coating process in the processing vacuum chamber may then continue, whereas the output vacuum chamber is emptied. In this emptying process, the pressure in the output vacuum chamber is increased to atmospheric pressure, the release opening is opened for withdrawal of the full roll of coated web material, the release opening is again closed, and the pressure is lowered to a vacuum pressure level.

The process may be repeated for as many times as needed or found suitable for other reasons, such as the need for maintenance, etc.

The process also enables continuous coating of one side of a web material, or continuous coating of two sides of the web material, or continuous application of two coating layers, i.e. a double coating, on one or both sides of the web material.

The in-line web material processing machine may further comprise an extrusion or lamination unit for forming a film on the coating of the web material to be processed. Thus, in addition to the coating, preferably forming the barrier layer on the web material, an additional layer may be added. This additional layer is preferably arranged on-top of the barrier layer. This additional layer may e.g. be a polymeric layer, forming a protective layer over the barrier layer. Additionally, or alternatively, the coating and the film of the second coating material may both act as barriers blocking moisture and/or gases from passing through the coated material. Also, or additionally, the film provides a protective layer, alleviating the risk of contamination and/or mechanical damage.

The extrusion or lamination unit is optionally arranged inside the process vacuum chamber and positioned after the vacuum coating unit with respect to a processing direction. However, alternatively, the extrusion or lamination unit may be arranged outside the processing vacuum chamber. The extrusion or lamination unit may in such an embodiment be arranged in an in-line arrangement, but may alternatively be a separate, off-line unit, such as an off-line extrusion coater, for coating of at least one side of the web material. The coating or laminated layer may e.g. comprise polyolefin.

In an embodiment, a polyolefin layer/coating may be arranged on both sides of the web material, e.g. forming a layered structure comprising the layers: polyolefin; paperboard; metallized layer; and polyolefin. In another embodiment, a primer or barrier coating may be arranged on the paperboard prior to the arrangement of the metallized layer. Such an embodiment may comprise the layers: polyolefin; paperboard; primer or barrier coating; metallized layer; and polyolefin. In yet another embodiment, a polyolefin layer is arranged only on one side of the paperboard. Further, an additional barrier layer may be arranged between the paperboard and the metallized layer. Such an embodiment may comprise the layers: paperboard; barrier layer; metallized layer; and extrusion coated layer(s).

The in-line web material processing machine may additionally, or alternatively, comprise a printing unit to provide a print on a coated or non-coated side of the web material.

The vacuum in the processing vacuum chamber, the loading vacuum chamber and/or the output vacuum chamber may be provided by independently operable vacuum systems. If totally separated systems are used, each system uses its own equipment, such as vacuum pumps, and is independently controllable. However, it is also feasible to use one or more common vacuum pumps. In such an embodiment, the pump(s) may be used intermittently to evacuate pressure from the chambers in turns.

The vacuum pressure in the processing vacuum chamber, and preferably also in the other vacuum chambers, is preferably below 1×10⁻¹ Torr (1.3×10⁻⁵ Mpa) and more preferably below 1×10⁻² Torr (1.3×10⁻⁶ Mpa).

The web material may have a width in the range of 0.5-4 m, and preferably in the range of 1-3 m, and more preferably in the range of 1.5-2.5 m, such as about 2 m.

The supply rolls may have a diameter in the range of 0.75-2.5 m, and preferably in the range of 1.0-2.5 m, and more preferably in the range of 1.5-2.0 m.

In an automated process, involving the roll/reel changes at the input side, and optionally at the output side, the web material speed through the coating is preferably over 100 m/min, and preferably over 500 m/min, and most preferably 700 m/min or more.

The coating may be arranged on one side of the web material, or on two sides. The coating may further be provided as a single coating or as a double coating. If more than one coating layers are to be provided, more than one vacuum coating units may also be used.

According to another aspect of the invention, there is provided a method for vacuum coating of a web material comprising:
coating a web material in a process vacuum chamber;
providing an uncoated web material in loading vacuum chamber; and
opening a closure between said process vacuum chamber and said loading vacuum chambers and performing an automatic reel change under vacuum.

Similar additional features and details as disclosed in relation to the first discussed embodiment are possible also in respect of this second aspect, and the same or similar advantages and benefits are obtained.

### BRIEF DESCRIPTION OF THE DRAWINGS

The present invention will be described in more detail with reference to the appended drawings, showing currently preferred embodiments of the invention.

FIG. 1 is a schematic illustration of an in-line web material processing machine for producing a coated material, in accordance with an embodiment.

FIG. 2 is a schematic illustration of an in-line web material processing machine for producing a coated material, in accordance with another embodiment.

FIGS. 2-6 are schematic illustrations of various vacuum chamber configurations useable in combination with the embodiments of FIGS. 1 and 2.

FIGS. 7a-c are illustrations of an automatic reel changer system in accordance with an embodiment and illustrating different steps during a reel change.

FIGS. 8a-c are illustrations of an automatic reel changer system in accordance with another embodiment and illustrating different steps during a reel change.

FIG. 9 is a schematic illustration of a coating processes according to various possible embodiments.

### DETAILED DESCRIPTION OF CURRENTLY PREFERRED EMBODIMENTS

In the following detailed description, preferred embodiments of the present invention will be described. However, it is to be understood that features of the different embodiments are exchangeable between the embodiments and may be combined in different ways, unless anything else is specifically indicated. Even though in the following description, numerous specific details are set forth to provide a more thorough understanding of the present invention, it will be apparent to one skilled in the art that the present invention may be practiced without these specific details. In other instances, well known constructions or functions are not described in detail, so as not to obscure the present invention.

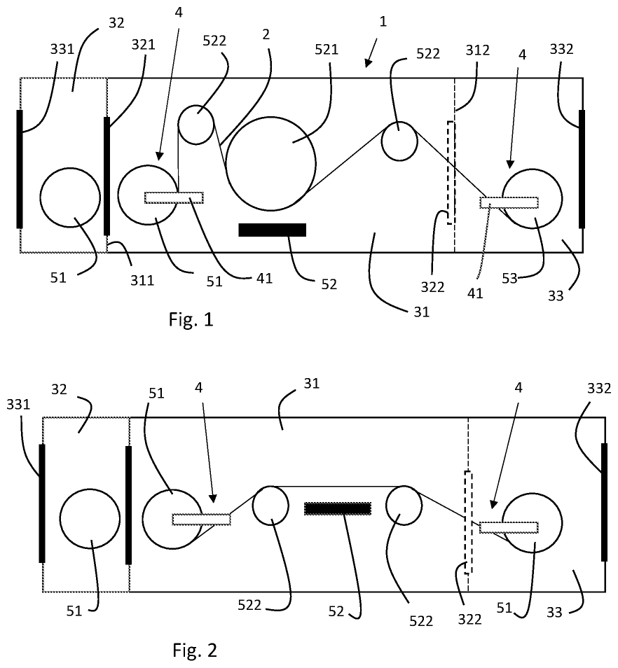

With reference to FIG. 1, an in-line web material processing machine 1 for producing a coated material 2 comprises two or more vacuum chambers 3, including a process vacuum chamber 31, a loading vacuum chamber 32 and, optionally, an output vacuum chamber 33. The vacuum chambers may be operated independently of each other. In an embodiment, the vacuum chambers may be operated by independent vacuum systems, each having separate vacuum pumps. However, the same pump may also be used for two or more of the vacuum chambers, and may e.g. be arranged to operate intermittently and in sequence on the different vacuum chambers.

The two or more vacuum chambers are preferably arranged adjacent each other, and are in communication with each other through an opening. An opening may be formed in a common wall separating two of the chambers, or through a tubular element connecting two of the chambers.

For example, the loading vacuum chamber 32 and the process vacuum chamber 31 may be separated by a common wall 311. Additionally, or alternatively, the process vacuum chamber 31 and the output vacuum chamber 33 may be separated by a common wall 312.

The opening(s) between the chambers can be closed by a closure, moveable between a closed state and an open state. The closure may e.g. be realized as a roller gate, a door, a hatch, a sliding door, or the like. The closure(s) may be operated by an electric motor, and may be controlled by a controller. Alternatively, the closure(s) may be operated pneumatically or hydraulically.

In the embodiment of FIG. 1, an inlet closure 321 is arranged between the process vacuum chamber 31 and the loading vacuum chamber 32. The inlet closure 321 is arranged to be moved between a closed state, in which the process vacuum chamber 31 and the loading vacuum chamber 32 are separated from each other, to an open state, in which access is provided between the process vacuum chamber 31 and the loading vacuum chamber 32.

Similarly, in case an output vacuum chamber 33 is provided, an outlet closure 322 may be arranged between the process vacuum chamber 31 and the output vacuum chamber 33. The outlet closure 322 is arranged to be moved between a closed state, in which the processing vacuum chamber 31 and the output vacuum chamber 33 are separated from each other, to an open state, in which access is provided between the processing vacuum chamber 31 and the output vacuum chamber 33.

The loading vacuum chamber is further provided with a loading opening to the exterior, with a loading closure 331. The loading closure may be closed when there is vacuum in the loading vacuum chamber 32, but may be opened when there is no vacuum, and when access to the loading vacuum chamber for loading is needed.

The output vacuum chamber may similarly be provided with an offloading opening to the exterior, with an offloading closure 332. The offloading closure may be closed when there is vacuum in the output vacuum chamber, but may be opened when there is no vacuum, and when access to the output vacuum chamber 33 for offloading is needed. In embodiments where there is no output vacuum chamber, the offloading closure 332 may instead be arranged in an offloading opening of the process vacuum chamber 31.

The process vacuum chamber 31 houses processing equipment for providing a coating on a web material. In the illustrative example, the process vacuum chamber 31 accommodates an unwinder reel holder 41 for holding a first supply roll 51 of web material 2 to be processed and a vacuum coating unit 52 for deposing a coating on the web material 2.

The web material to be processed, and supplied on the supply rolls, is preferably a fiber-based material, and preferably a paperboard material. The web material is preferably relatively thick, with a grammage of at least 150 g/m², and a thickness of at least 300 microns. However, materials with lower grammage, such as of 60 g/m² or more, may also be used, in particular for materials having one or more layers of low density, such as less than 600 kg/m³.

The supply roll may e.g. have a width in the range of 0.5-4 m, and in particular 1.5-3 m, such as 2 m, and may have a diameter in the range of 1-3 m, such as 1.5 or 2 m. A supply roll of relatively thick paperboard may e.g. contain a length of web material of 5 -25 km, such as 10 km.

The vacuum coating unit, also referrable to as vacuum coater, may be of a type as is per se previously known. The vacuum coating unit may e.g. be realized as disclosed in US 2020/0165721 and/or WO 2022/090337, both said documents hereby being incorporated in their entirety by reference. Preferably, the vacuum coating unit is a vapor deposition unit. The vapor deposition unit may be a physical vapor deposition unit using a coating material in a liquid or solid state, an atomic layer deposition unit, or a chemical vapor deposition unit using a chemical vapor. This may also be referred to as metallization. The coating may e.g. comprise or consist of aluminum or aluminum oxide. The coating preferably forms a barrier against liquids, such as water, and/or gases, such as vapor or oxygen. The coating preferably forms a gas and/or liquid impermeable barrier layer.

According to an embodiment the vacuum coating unit 52 comprises an area for guiding the web material. This could be for example a processing drum 521 for supporting the web material to be processed.

Moreover, one or more rollers or drums 522 may be provided to facilitate the flow of the web material 2 through the processing vacuum chamber, from the unwinding position and the supply roll, and the rewinding position, and an optional rewinding roll.

Another possibility for coating the web material, and as shown in FIG. 2, is to guide the web material in a free span manner without the use of a processing drum. In the free span arrangement the web material to be vacuum coated is held in an unsupported/free span arrangement between supporting rollers 522 with the evaporation source and evaporant material applied via evaporation and condensing the evaporant on the web material in an unsupported and uncooled manner.

Preferably, the machine operates in a roll-to-roll process, in which the web material to be processed is provided on a supply roll and the processed, coated web material is wound on rewind roll. However, the processed, coated web material may also be cut into sheets, in a roll-to-sheet process, or be taken care of in other ways.

During production, the loading closure 331 of the loading vacuum chamber 32 may be opened and a supply roll 51 may be loaded into the loading vacuum chamber 32, at atmospheric pressure. At the same time, the process may be running with another supply roll 51 in the processing vacuum chamber 31 at vacuum pressure. The inlet closure 321, forming a passage between the loading vacuum chamber 32 and the processing vacuum chamber 31, is at this time closed. When the new supply roll 51 has been loaded into the loading vacuum chamber 32, the loading closure 331 of the loading vacuum chamber 32 may be closed and air and moisture be evacuated to form a vacuum in the loading vacuum chamber 32.

Before the web material on the supply roll 51 in the processing vacuum chamber 31 has been unwounded to its end, and when the vacuum pressure in the loading vacuum chamber 32 has reached an acceptable pressure level, the inlet closure 321 between the loading vacuum chamber 32 and the processing vacuum chamber 31 is opened. At this time, the pressure levels of the two chambers are preferably essentially the same. However, a slight difference in pressure may also be acceptable. The pressure within the chambers will be equalized in both chambers once the inlet closure 321 has been opened, thereby forming an open passage between the chambers.

When the inlet closure 321 has been opened, i.e. brought to the open state, the new supply roll 51 may be moved into the process vacuum chamber. The old supply roll 51, already in use in the processing vacuum chamber, could then be exchanged to the new supply roll, coming from the loading vacuum chamber. The switch is performed by an automatic reel change system 4, as per se known in the art.

The web material from the fresh supply roll 51 is preferably spliced to the web material of the old supply role 51, thereby allowing the process in the processing vacuum chamber to continue without interruption.

After the change of supply rolls 51, or alternatively during or prior to this, the inlet closure 321 between the loading vacuum chamber 32 and the processing vacuum chamber 31 is again closed. The coating process in the processing vacuum chamber 31 may then continue, whereas the loading vacuum chamber 32 is reloaded. In this reloading process, the pressure in the loading vacuum chamber is increased to atmospheric pressure, the loading closure 331 is opened for introduction of a new supply roll, the loading closure 331 is again closed, and the pressure is lowered to a vacuum pressure level.

The process may be repeated for as many times as needed or found suitable for other reasons, such as the need for maintenance, etc.

The in-line web material processing machine may further comprise a rewinder reel holder 41 for holding a rewinding reel for rewinding of the coated web material. Hereby, the processed, coated material may be assembled on a rewinding roll 52. In this case, the process may be a roll-to-roll process. Such a process is generally the most efficient. However, alternatively the coated material may also be cut into sheets, e.g. already in the processing vacuum chamber, or outside this chamber, in a roll-to-sheet process. The process may also comprise edge trimming of the processed web material.

In a roll-to-roll process, the rewinding reel holder is preferably arranged in the processing vacuum chamber 31.

In case rewinding takes place inside the processing vacuum chamber 31, it may be contemplated to have the rewinding roll to be larger than the supply rolls, thereby allowing the web material of more than one supply roll to be wounded onto a single rewinding roll. Additionally, or alternatively, it is also feasible to temporarily stop the coating process to change the rewinding roll. Hereby, the pressure in the processing vacuum chamber may be allowed to rise to atmospheric pressure, and the processing vacuum chamber may then be opened to extract the full rewind roll and replace it with an empty reel. The processing vacuum chamber may then again be closed and evacuated to an adequate vacuum level, whereby the coating process may continue as before.

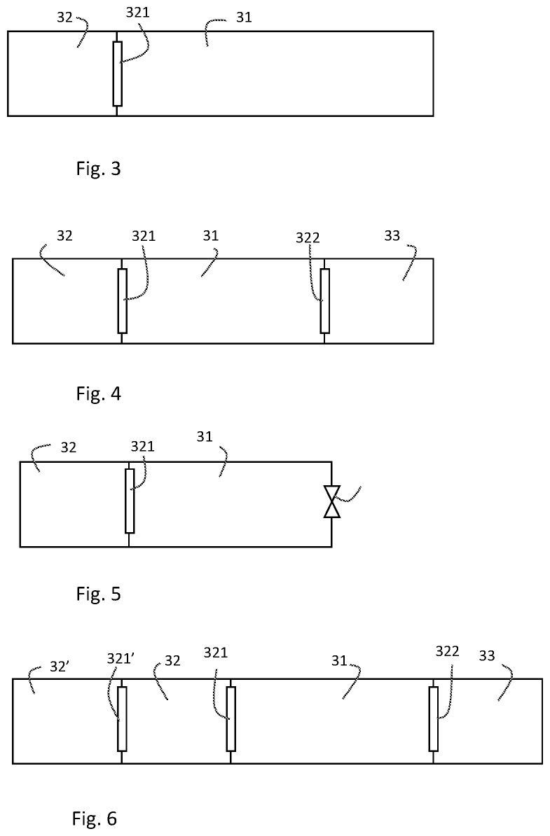

An embodiment suitable for such use is schematically illustrated in FIG. 3. Here, two vacuum chambers are used-the loading vacuum chamber 32 and the processing vacuum chamber 31. In this embodiment, it is contemplated that rewinding of the coated web material is made inside the processing vacuum chamber. For offloading of a full rewinding roll, the processing vacuum chamber needs to return to ambient pressure and be opened.

However, in an alternative embodiment, as illustrated schematically in FIG. 4, a change of rewind rolls is also performed while still maintaining vacuum in the processing vacuum chamber during the process. Such an exchange of rolls may preferably be performed in a manner similar to the above-discussed exchange of supply rolls.

In the embodiment of FIG. 4, three vacuum chambers are used-the loading vacuum chamber 32, the processing vacuum chamber 31 and an output vacuum chamber 33. In this embodiment, offloading of a full rewinding roll may take place by a second automatic reel change system 4, whereby the rewinding roll to be offloaded may be brought from the processing vacuum chamber 31 into the output vacuum chamber 33, and then subsequently be removed from the output vacuum chamber. Hereby, offloading of a full rewinding roll may take place while vacuum is constantly maintained in the processing vacuum chamber 31.

Hereby, the coating process may continue uninterrupted, even during an exchange of the rewinding rolls. Before the coated web material on the rewind roll in the processing vacuum chamber has been re-wounded to its full capacity, it is assured that the vacuum pressure in the output vacuum chamber 33 has reached an acceptable pressure level. The outlet closure 322 between the output vacuum chamber 33 and the processing vacuum chamber 31 is then opened. At this time, the pressure levels of the two chambers are preferably essentially the same. However, a slight difference in pressure may also be acceptable.

When the outlet closure 322 has been opened, i.e. brought to the open state, the full rewinding roll 53, already in use in the processing vacuum chamber 31, could be exchanged to the new rewinding roll 53, coming from the output vacuum chamber 33. The switch is performed by the second automatic reel change system 4, as per se known in the art.

The coated web material is then preferably cut and the end attached to the fresh roll, thereby allowing the process in the processing vacuum chamber 31 to continue without interruption.

After the change of rewind rolls 53, the outlet closure 322 between the output vacuum chamber 33 and the processing vacuum chamber 31 is again closed. The coating process in the processing vacuum chamber 31 may then continue, whereas the output vacuum chamber is offloaded and emptied. In this emptying process, the pressure in the output vacuum chamber 33 is increased to atmospheric pressure, the offloading, release opening 332 is opened for withdrawal of the full roll of coated web material, the release opening 332 is again closed, and the pressure is lowered to a vacuum pressure level.

The process may be repeated for as many times as needed or found suitable for other reasons, such as the need for maintenance, etc.

Alternatively, as schematically illustrated in FIG. 5, the coated material may be arranged to be moved out from the processing vacuum chamber 31 through an opening 322′ enabling vacuum to be maintained in the processing vacuum chamber 31, to be wounded on a rewinding roll outside the processing vacuum chamber 31. Such an opening may e.g. be realized by a narrow slit opening, a gap sluice, or the like, as is per se known in the art.

More than one loading vacuum chambers may also be used. Such an embodiment is illustrated in FIG. 6. In this embodiment, a first loading vacuum chamber 32′ may be used to evacuate moisture from the supply roll in an initial stage, before entering the second loading vacuum chamber 32. This may be used to use the processing vacuum chamber 32 more efficiently, in particular for fast coating processes.

The automatic reel change system may be of any type per se known in the art, and used for example for reel changes in printing presses. Such automatic reel change systems are e.g. known from U.S. Pat. Nos. 3,907,235, 4,111,741, 4,077,580, 4,278,213, 4,233,104, 4,875,633, etc, all of said documents hereby being incorporated in their entirety by reference.

Due to the automatic reel change system, a so-called flying roll change can be performed, to that upon depletion of a roll of material, the coating process need not be stopped. In this process, the old, depleted or almost depleted supply roll is exchanged to a new supply roll. The new web material, of the new supply roll, is preferably spliced or in other ways connected to the old web material, of the old supply roll. Hereby, a continuous, endless web material is formed. The splicing may e.g. be obtained by adhesive tapes, by adhesive, or the like. For this purpose, the new supply roll may be provided with an adhesive tape, gluing spots or the like, on an outer layer, for use in accomplishing a connection with the web material of the roll of material which is running out.

During on-the-fly roll change, the fresh web material is then accelerated to a circumferential speed corresponding to the web speed of the established roll of material. In the course of the actual web change, the start of the web of the fresh roll of material is connected with the web of material on the roll of material which is running out, and the web of material on the roll of material which is running out is cut at substantially the same time. In this way, the start of the web of the fresh web of material is drawn into the coating process by the old web of material and a stoppage of the process is avoided.

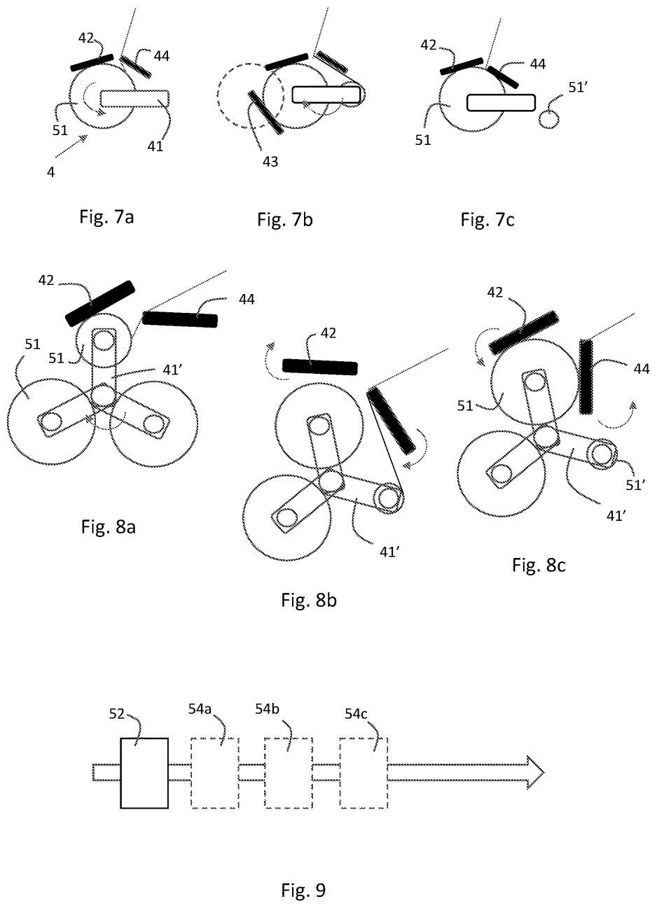

Two embodiments of automatic reel change systems are shown in FIGS. 7a-c and FIGS. 8a-c.

In the embodiment of FIGS. 7a-c, the automatic reel change system 4 comprises a reel holder 41 in the form of a rotatable reel arm, having two separate reel holding positions arranged at the opposed ends. A drive belt 42 is arranged to rotate the supply roll 51. FIG. 7a shows a state in which a relatively full supply roll 51 is provided in the reel holder 41 and unwinding of the reel is made continuously. The rotatable reel arm can be rotated while the roll is unwound. In FIG. 7 b, the supply roll is almost empty, and need to be changed. A new supply roll 51 is then moved towards the reel holder 41, e.g. by pivotable arms 43. In the state illustrated in FIG. 7c, the new supply roll 51 is accelerated up to production speed, and a splicer 44 splices the new web to the old web at operational speed. The used reel 51′ is at the same time cut off and removed from the reel holder 41.

In the embodiment of FIGS. 8a-c, the automatic reel change system 4 comprises a reel holder 41′ in the form of a rotatable reel star with three arms, having three separate reel holding positions arranged at the ends of the arms. A drive belt 42 is arranged to rotate the supply roll 51. FIG. 8a shows a state in which a supply roll 51 is being unwound and held in the upwardly directed reel holding arm. In FIG. 8b, the supply roll is almost empty, and need to be changed. A new supply roll 51 is then moved towards the uppermost position, by rotation of the reel holder 41′. In the state illustrated in FIG. 8c, the new supply roll 51 is accelerated up to production speed, and a splicer 44 splices the new web to the old web at operational speed. The used reel 51′ is at the same time cut off from the reel holder 41′.

In the so far discussed embodiments, the processing involves only a single vacuum coating step, performed by the vacuum coating unit. However, additional process steps could also be used, such as one or more additional coating steps, performed by one or more additional vacuum coating units. Provision of a film layer over the coating, such as by an extrusion or lamination unit, could also be contemplated. Additionally, or alternatively, a printing unit may be provided to print text or pictures on the web material.

Such embodiments, which may be used in combination with any of the above-discussed embodiments, are schematically illustrated in FIG. 9. In this embodiment, a number of processing units are illustrated, as dashed boxes, in addition to the vacuum coating unit. In embodiments, all of these additional processing units 54a-c may be used, or alternatively only one or two of them, in any combination.

In an embodiment, the in-line web material processing machine may further comprise a second coating unit 54a. The second coating unit may be of the same type as the vacuum coating unit discussed in the foregoing, but may also be of a different type.

Additionally, or alternatively, the in-line web material processing machine may further comprise an extrusion or lamination unit 54b, for forming a film on the coating of the web material to be processed. Thus, in addition to the coating, preferably forming the barrier layer on the web material, an additional layer may be added. This additional layer is preferably arranged on-top of the barrier layer. This additional layer may e.g. be a polymeric layer, forming a protective layer over the barrier layer. Additionally, or alternatively, the coating and the film of the second coating material may both act as barriers blocking moisture and/or gases from passing through the coated material. Alternatively, or additionally, the film may provide a protective layer, alleviating the risk of contamination and/or mechanical damage.

The optional additional coating unit, and optional extrusion or lamination unit, may be arranged inside the process vacuum chamber 31, and preferably positioned after the vacuum coating unit 52 with respect to a processing direction. However, alternatively, optional additional coating unit and extrusion or lamination unit may be arranged outside the processing vacuum chamber 31.

A printing unit 54c may also be used, to print text or other forms of visual information on the coated web material. The printing unit may also be arranged inside the processing vacuum chamber 31, or alternatively outside this chamber.

The person skilled in the art realizes that the present invention by no means is limited to the preferred embodiments described above. On the contrary, many modifications and variations are possible within the scope of the appended claims. For example, more than two vacuum chambers may be used, such as three or four. Further, different types of vacuum coating units and automatic reel change systems may be employed. Further, even though a preferred application is coating of paperboard, other web materials may also be used, such as thinner paper, and plastic materials, such as polymer based materials. Other types of coatings may also be used, such as ceramic coatings, carbon containing coatings, etc.

1. An in-line web material processing machine for producing a coated material comprising:
a process vacuum chamber housing an unwinder reel holder for holding a first supply roll of web material to be processed and a vacuum coating unit for deposing a coating on the web material;
a loading vacuum chamber housing a second supply roll of web material to be processed;
an inlet closure arranged between said process vacuum chamber and said loading vacuum chamber, the inlet closure configured to move between a closed state, in which the processing vacuum chamber and the loading vacuum chamber are separated from each other, and an open state, in which access is provided between the processing vacuum chamber and the loading vacuum chamber; and
an automatic reel change system configured to move said second supply roll of web material from said loading vacuum chamber to said process vacuum chamber under vacuum when said inlet closure is in the open state and to change a supply roll on said unwinder reel holder from said first supply roll to said second supply roll under vacuum.

2. The in-line web material processing machine of claim 1, wherein the web material to be processed is at least one of paperboard material, thick paper, and low density, bulky paper.

3. The in-line web material processing machine of claim 1, wherein the web material to be processed has a grammage of at least 150 g/m².

4. The in-line web material processing machine of claim 1, wherein the web material to be processed has a density less than 950 kg/m³.

5. The in-line web material processing machine of claim 1, wherein the web material to be processed has a thickness of at least 300 microns.

6. The in-line web material processing machine of claim 1, wherein the vacuum coating unit is configured to deposit a coating on the web material of a vapor deposited inorganic material.

7. The in-line web material processing machine of claim 1, further comprising:
a rewinder reel holder for holding a rewinding reel for rewinding of the coated material.

8. The in-line web material processing machine of claim 7, wherein the rewinding reel holder is arranged in the processing vacuum chamber.

9. The in-line web material processing machine of claim 8, further comprising:
an output vacuum chamber;
an outlet closure arranged between said process vacuum chamber and said output vacuum chamber, the outlet closure configured to move between a closed state, in which the processing vacuum chamber and the output vacuum chamber are separated from each other, to an open state, in which access is provided between the processing vacuum chamber and the output vacuum chamber; and
a second automatic reel change system configured to change a rewinding roll on said rewinder reel holder from a first rewinder roll to a second rewinder roll under vacuum when said outlet closure is in the open state.

10. The in-line web material processing machine of claim 1, further comprising:
an extrusion or lamination unit for forming a film on the coating of the web material to be processed.

11. The in-line web material processing machine of claim 10, wherein the extrusion or lamination unit is arranged inside the process vacuum chamber and positioned after the vacuum coating unit with respect to a processing direction.

12. The in-line web material processing machine of claim 1, wherein a vacuum in the processing vacuum chamber and a vacuum in the loading vacuum chamber are provided by independently operable vacuum systems.

13. A method for vacuum coating of a web material comprising:
coating a web material in a process vacuum chamber;
providing an uncoated web material in a loading vacuum chamber; and
opening a closure between said process vacuum chamber and said loading vacuum chamber and performing an automatic reel change under vacuum.
